(19) United States
(12) Patent Application Publication
(10) Pub. No.: US 2019/0268008 A1
(43) Pub. Date: Aug. 29, 2019

(54) Apparatus for Digital Phase-Locked Loop and Associated Methods

(71) Applicant: Silicon Laboratories Inc., Austin, TX (US)

(72) Inventors: John M. Khoury, Austin, TX (US); Peijun Wang, Austin, TX (US)

(21) Appl. No.: 15/904,173

(22) Filed: Feb. 23, 2018

(51) Int. Cl. H03L 7/099; H03L 7/24; G01K 7/02

(52) U.S. Cl. CPC H03L 7/0991; G01K 7/021; H03L 7/24

(57) ABSTRACT

An apparatus includes a digital phase-locked loop (DPLL). The DPLL includes a digital phase and frequency detector coupled to receive a reference signal and to generate a first set of output signals, and a digital loop filter that receives the first set of output signals of the phase and frequency detector output and generates an integral path control signal and a proportional path control signal. The DPLL further includes a digital to analog converter (DAC) to convert the integral path control signal and the proportional path control signal to a second set of output signals. The DPLL in addition includes a controlled oscillator (CO) to generate an output signal in response to the second set of output signals.

### TECHNICAL FIELD

The disclosure relates generally to signal generation apparatus and methods and, more particularly, to apparatus including digital phase-locked loops (DPLLs), and associated methods.

### BACKGROUND

With the increasing proliferation of wireless technology, such as Wi-Fi, Bluetooth, and mobile or wireless Internet of things (IoT) devices, more devices or systems incorporate RF circuitry, such as receivers and/or transmitters. To reduce the cost, size, and bill of materials, and to increase the reliability of such devices or systems, various circuits or functions have been integrated into integrated circuits (ICs). For example, ICs typically include receiver and/or transmitter circuitry. Typically, receiver and/or transmitter circuitry use one or more signals to perform a variety of functions, such as clocking circuitry (e.g., analog-to-digital converters (ADCs)), image reject calibration, mixing radio frequency (RF) signals to baseband or an intermediate frequency (IF), mixing a baseband or IF signal to RF signals, and the like.

The description in this section and any corresponding figure(s) are included as background information materials. The materials in this section should not be considered as an admission that such materials constitute prior art to the present patent application.

### SUMMARY

A variety of apparatus and associated methods are contemplated according to exemplary embodiments. According to one exemplary embodiment, apparatus includes a DPLL. The DPLL includes a digital phase and frequency detector coupled to receive a reference signal and to generate a first set of output signals, and a digital loop filter that receives the first set of output signals of the phase and frequency detector output and generates an integral path control signal and a proportional path control signal. The DPLL further includes a digital to analog converter (DAC) to convert the integral path control signal and the proportional path control signal to a second set of output signals. The DPLL in addition includes a controlled oscillator (CO) to generate an output signal in response to the second set of output signals.

According to another exemplary embodiment, an apparatus a DPLL. The DPLL includes a plurality of up-down counters, and a time-to-digital converter (TDC) coupled to the plurality of up-down counters. The DPLL further includes a fine frequency detector coupled to the plurality of up-down counters. In addition, the DPLL includes a coarse frequency detector coupled to the plurality of up-down counters.

According to another exemplary embodiment, an apparatus includes a DPLL. The DPLL includes a digital phase and frequency detector. The digital phase and frequency detector includes a time-to-digital converter (TDC), a fine frequency detector, and a coarse frequency detector. The DPLL achieves frequency lock without using a calibration operation.

### BRIEF DESCRIPTION OF THE DRAWINGS

The appended drawings illustrate only exemplary embodiments and therefore should not be considered as limiting the scope of the application or the claims. Persons of ordinary skill in the art will appreciate that the disclosed concepts lend themselves to other equally effective embodiments. In the drawings, the same numeral designators used in more than one drawing denote the same, similar, or equivalent functionality, components, or blocks.

FIG. 1 shows a circuit arrangement for a DPLL according to an exemplary embodiment.

FIG. 2 shows a circuit arrangement for a DPLL according to an exemplary embodiment.

FIG. 3 shows a circuit arrangement for a DPLL according to an exemplary embodiment.

FIG. 4 shows a circuit arrangement for an RF receiver, including a DPLL, according to an exemplary embodiment.

FIG. 5 shows a circuit arrangement for an RF receiver, including a DPLL, according to an exemplary embodiment.

FIG. 6 shows a circuit arrangement for an RF receiver, including a DPLL, according to an exemplary embodiment.

FIG. 7 shows a circuit arrangement for an RF transmitter, including a DPLL, according to an exemplary embodiment.

FIG. 8 shows a circuit arrangement for an RF communication system according to an exemplary embodiment.

FIG. 9 shows a circuit arrangement for an IC, including a receiver that includes one or more DPLLs, according to an exemplary embodiment.

FIG. 10 shows a circuit arrangement for an IC, including a transmitter that includes one or more DPLLs, according to an exemplary embodiment.

### DETAILED DESCRIPTION

The disclosed concepts relate generally to signal generation apparatus and related methods. More specifically, the disclosed concepts provide apparatus and methods for DPLLs. DPLLs according to various embodiments have a number of advantageous characteristics, which are described below in detail.

DPLLs according to various embodiments may be used in a variety of apparatus, subsystems, systems, modules, ICs, and the like. Without limitation, examples include RF receivers, RF transmitters, and RF transceivers.

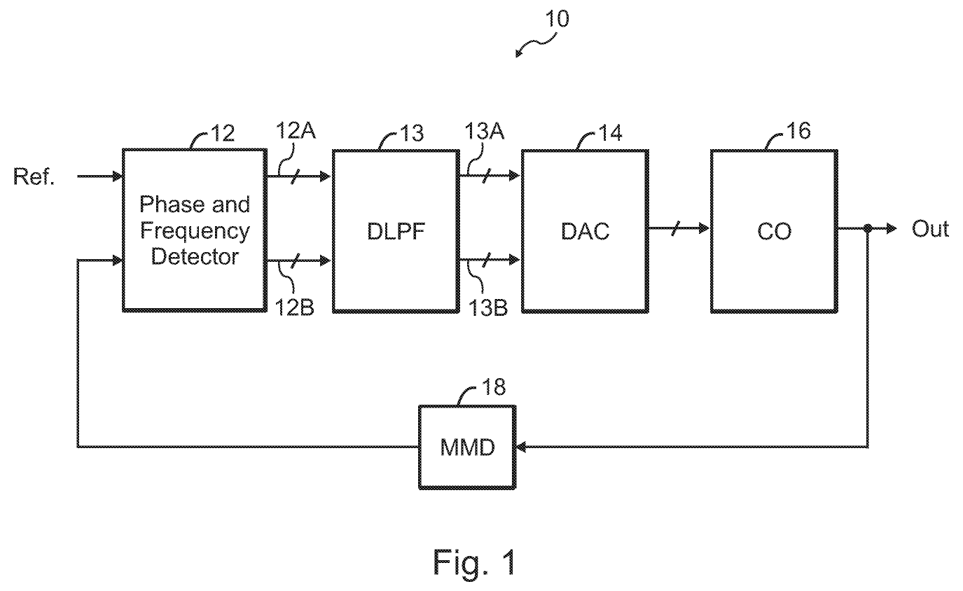

FIG. 1 shows a circuit arrangement for a DPLL 10 according to an exemplary embodiment. DPLL 10 includes digital phase and frequency detector 12. A reference signal, labeled “Ref.” is provided to one input of phase and frequency detector 12. A feedback signal, described below in detail, is provided to another input of digital phase and frequency detector 12.

Digital phase and frequency detector 12 compares the phase and frequency of the two input signals. As output signals, digital phase and frequency detector 12 provides signals 12A and 12B. Signal 12A corresponds to an integral control path in the feedback loop of DPLL 10. Conversely, signal 12B corresponds to a proportional control path in the feedback loop of DPLL 10.

Signals 12A and 12B are provided to the digital loop filter (DLPF) 13, which contains circuitry to perform integral and proportional signal processing functions. The outputs of DLPF 13, labeled 13A and 13B, are provided to digital-to-analog converter (DAC) 14. DAC 14 converts the digital signals 13A-13B to analog output signals that drive controlled oscillator (CO) 16. In response, ICO 16 generates an output signal of DPLL 10. In some embodiments, CO 16 may constitute a current-driven oscillator (ICO) driven by a current DAC (IDAC) 14. Alternatively, in some embodiments, CO 16 may constitute a voltage-controlled oscillator (VCO) driven by a voltage DAC (VDAC) 14.

The output signal of DPLL 10 is used in a negative feedback loop to reduce or minimize phase and frequency errors in DPLL 10. More specifically, the output signal of DPLL 10 is provided as an input signal to multi-modulus divider (MMD) 18. Multi-modulus divider (MMD) 18 divides the nominal (or desired) frequency of the output signal of DPLL 10 by a number that can be an integer or integer plus fraction. The negative feedback of the DPLL causes the MMD output signal to have the same frequency as the frequency of the reference signal.

The output of MMD 18 is provided as a second input to digital phase and frequency detector 12, as noted above. Thus, a negative feedback loop is realized in DPLL 10. The negative feedback loop acts to minimize the frequency and phase errors in the output signal of DPLL 10.

Note that MMD 18 may be optional in some embodiments. Specifically, if the desired output frequency of DPLL 10 is equal (or nearly equal in a practical implementation) to the reference frequency, MMD 18 may be omitted, and the output signal of DPLL 10 fed back to the input of digital phase and frequency detector 12.

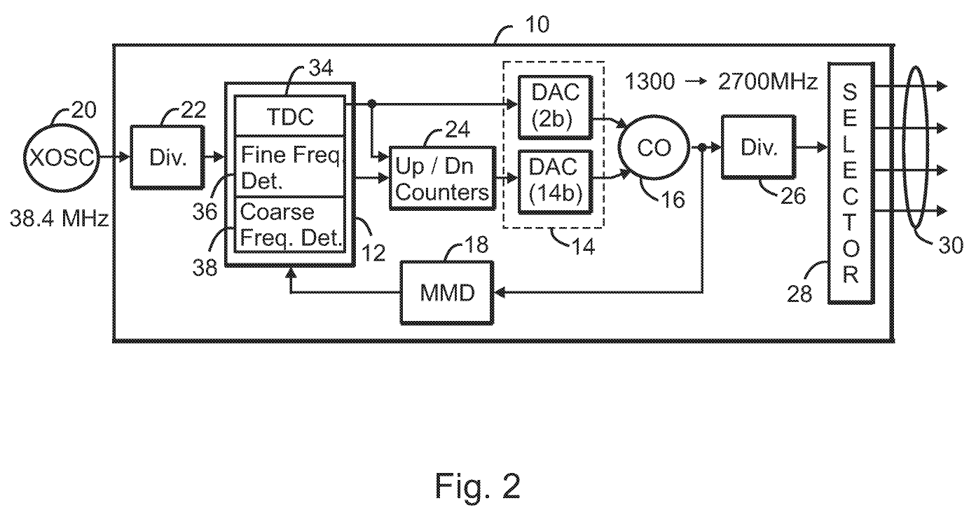

FIG. 2 shows a circuit arrangement that includes a DPLL 10 according to an exemplary embodiment. The figure provides a more detailed block diagram of DPLL 10 according to the exemplary embodiment shown. As noted above, in some embodiments, CO 16 may constitute a current-driven oscillator (ICO) driven by a current DAC (IDAC) 14. Alternatively, in some embodiments, CO 16 may constitute a voltage-controlled oscillator (VCO) driven by a voltage DAC (VDAC) 14.

Referring again to FIG. 2, source, such as a crystal-based oscillator (XOSC) 20 in the embodiment shown provides the reference signal. In the example shown the reference signal has a frequency of 38.4 MHz, although other values may be used, as persons of ordinary skill in the art will understand.

The reference signal drives an input of frequency divider 22. Frequency divider 22 divides the frequency of the reference signal in order to provide an output signal whose frequency is equal (or nearly equal in a practical implementation) to the feedback signal from MMD 18 (or from the output of ICO 16 if MMD 18 is omitted). The resulting signal at the output of divider 22 is fed to digital phase and frequency detector 12 as one input signal.

Divider 22 may perform frequency division using a desired divisor. In a particular example that uses a 38.4 MHz XOSC signal, divider 22 may divide by 1, 2, 3, . . . , 7, although other divisors may be used, as persons of ordinary skill in the art will understand.

Similar to the embodiment in FIG. 1, digital phase and frequency detector 12 also receives the output signal of MMD 18 as a second input. Note that MMD 18 may be omitted in some situations, as described above.

DPLL 10 uses two frequency detectors and one phase detector. More specifically, digital phase and frequency detector 12 includes time-to-digital converter (TDC) 34, fine-frequency detector 36, and coarse-frequency detector 38. Coarse frequency detector 38 brings the frequency of the output signal of CO 16 into about 12% of the target frequency (desired frequency of CO 16). In exemplary embodiments, coarse frequency detector 38 is implemented using counters, such as a set of digital down-counters, and other ways of implementing coarse frequency detector 38 are contemplated and may be used, as persons of ordinary skill in the art will understand.

Fine-frequency detector 36 works to acquire frequency lock from 25% down to 0%. Fine frequency detector 36 may be implemented in a variety of ways, for example, using a digital rotational detector or a quadri-correlator, as persons of ordinary skill in the art will understand.

TDC 34 captures phase and finally achieves both frequency and phase lock in DPLL 10. All three detectors (fine-frequency detector 36, coarse-frequency detector 38, and TDC 34) work in parallel. Once locked the two frequency detectors (fine frequency detector 36 and coarse frequency detector 38) measure frequency, but do not provide any updates at their respective outputs.

TDC 34 in the example shown includes a three-tap converter that performs phase detection. TDC 34 drives the proportional control path (2 bits in the example shown) of DPLL 10.

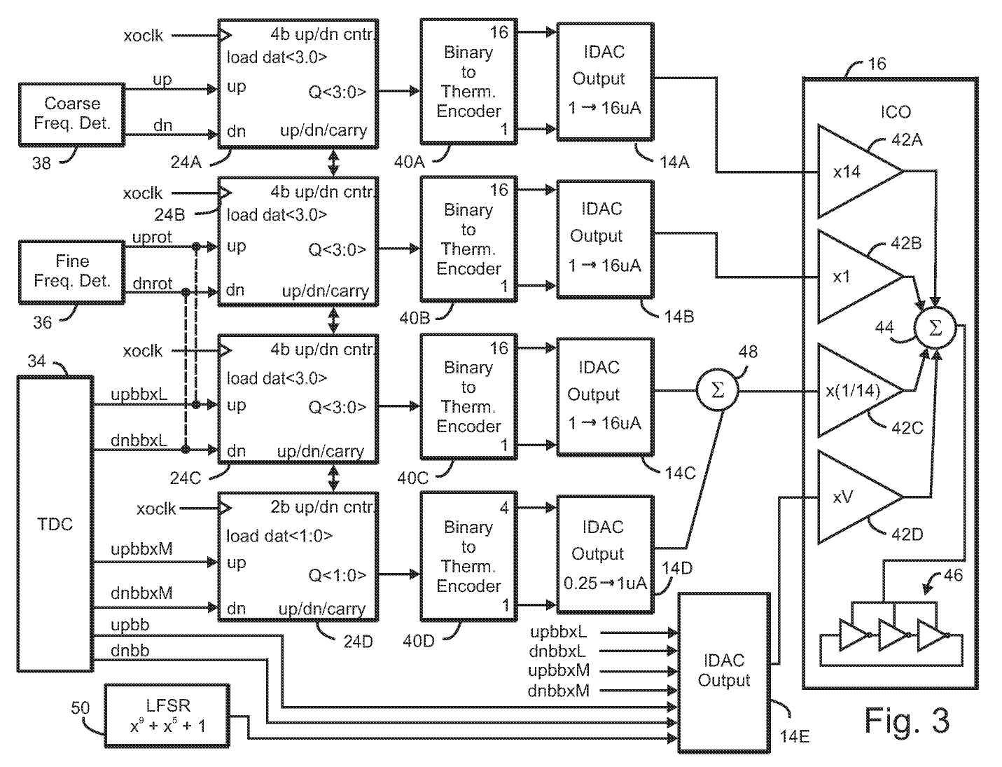

The three detectors (fine-frequency detector 36, coarse-frequency detector 38, and TDC 34) do not interfere with one another in a detrimental way, because the logic circuitry used to control DPLL 10 prioritizes the detectors and their associated weight (as described below in detail in connection with FIG. 3). Coarse-frequency detector 38 has the highest priority and the highest weight, as it directly updates the top (most significant) bits of up-down counters 24.

Fine-frequency detector 36 has second priority, and its weight is medium (between coarse-frequency detector 38, and TDC 34), and it drives the middle bits of up-down counters 24. Finally, TDC 34 has the lowest priority, and it drives the least significant bits (LSB) of up-down counters 24. By prioritizing and weighting the detectors in this way the total acquisition time of DPLL 20 is reduced compared to conventional PLLs or is minimized.

Digital phase and frequency detector 12 is coupled in a negative feedback loop that includes 14-bit up-down counters 24. Up-down counters 24 drive the integral control path (14 bits in the example shown) for DPLL 10. The output signal of up-down counters 24 drives 14 bits of the input of DAC 14. Conversely, the output signal of TDC 34 drives 2 bits of the input of DAC 14. (In the example shown, the 14 bits and 2 bits are shown as separate DACs to facilitate presentation and indicate signal flows, but do not necessarily imply or indicate an actual implementation, as persons of ordinary skill in the art will understand.)

The output signal of DAC 14 drives CO 16. The frequency of the output signal of CO 16 varies in response to the value of the output signal of DAC 14. Thus, the output signal of TDC 34 and the output signals of up-down counters 24 control or correct the frequency of the output signal of CO 16 in a feedback loop in order for DPLL 10 to achieve frequency lock. In the particular embodiment noted above, using an XOSC output signal of 38.4 MHz, the output signal of CO 16 has a frequency range of 1,300 to 2,700 MHz.

The output signal of CO 16 is fed to MMD 18 (if used) or to digital phase and frequency detector 12 (if MMD 18 is omitted). The output signal of CO 16 also feeds the input of frequency divider 26. Frequency divider 26 is optional, and if used, divides the frequency of the output signal of CO 16 in order to provide an output signal with a desired frequency.

In the particular embodiment noted above, using an XOSC output signal of 38.4 MHz, frequency divider 26 provides selectable divisors of 1, 2, 4, 6, 8, 10, 12, and 14. The output signal of frequency divider 26 drives the input of selector 28. Selector 28, which may be realized using a multiplexer or similar circuitry, allows the output signal of DPLL 10 to be routed to one of four different destinations within the chip or IC. In the particular embodiment noted above, using an XOSC output signal of 38.4 MHz, selector 28 provides output signals of 2.4 GHz (for RF receive or RX operation), a sub-GHz signal for RX operation, a 2.4 GHz or sub-GHz signal (for RF transmit or TX operation), and a signal with a suitable frequency for clocking an IF ADC (the frequency of the signal depends on the specifics of the implementation of the ADC). As persons of ordinary skill in the art will understand, however, other signals with different frequencies may be generated by making appropriate modifications.

Note that depending on the mode of operation, DPLL 10 operates as either a Type 1 or Type 2 PLL. Specifically, while the frequency of the output signal of DPLL 10 is being corrected, DPLL 10 operates as a Type 2 PLL, i.e., both the integral and proportional path controls are active. Conversely, when the frequency of the output signal of DPLL 10 has been corrected and the phase has been acquired, DPLL 10 operates as a Type 1 PLL, i.e., the proportional path control is active.

FIG. 3 shows a circuit arrangement for a DPLL according to an exemplary embodiment. More specifically, the figure illustrates more details of an implementation of DPLL 10 in FIG. 2 according to an exemplary embodiment. As noted above, in some embodiments, CO 16 may constitute a current-driven oscillator (ICO) driven by a current DAC (IDAC) 14. Alternatively, in some embodiments, CO 16 may constitute a voltage-controlled oscillator (VCO) driven by a voltage DAC (VDAC) 14. Thus, although the exemplary embodiment in FIG. 3 shows an ICO driven by IDACs, in alternative embodiments VCOs driven by VDACs may be used by making appropriate modifications, as persons of ordinary skill in the art will understand.

Referring again to FIG. 3, in particular, up-down counters 24 are implemented as a bank of four counters, three 4-bit up-down counters 24A-24C, and one 2-bit up-down counter 24D. Furthermore, note that binary to thermometer encoders 40A-40D are coupled to the outputs of up-down counters 24A-24D, respectively. Binary to thermometer encoders 40A-40D encode the output signals of up-down counters 24A-24D, respectively.

Binary to thermometer encoders 40A-40D are used to drive current-mode DACs 14A-14D, which control the instantaneous frequency of the output signal of ICO 16. In the embodiment shown, thermometer-encoded IDACs are used, as opposed to binary-weighted implementations, to minimize current glitches that might result in increased timing jitter and phase noise in the output signal of ICO 16. The thermometer encoding is performed for each four bits of counters 24A, 24B, 24C and the two bits of counter 24D. A separate thermometer-weighted IDAC 14E is driven by TDC 34. The thermometer-weighted IDACs are then scaled and added in the current domain, internally to ICO 16, as described below in detail. The scaling in ICO 16 is depicted with current amplifiers or scaling circuits 42A, 42B, 42C and 42D. Scaling is designed with a radix less than 2 (e.g., 1.6) to create overlap in the current-to-frequency characteristic of ICO 16. The overlap prevents the loop from locking at a point on the ICO's current-to-frequency curve that causes relatively large glitches or transients due to a few least-significant bit (LSB) changes in the DAC values.

Note that in the exemplary embodiment shown DAC 14 is implemented as five current-mode DACs (IDACs), labeled 14A-14E. The outputs of binary to thermometer encoders 40A-40D drive the inputs of DACs 14A-14D, respectively. The output signals of TDC 34 and linear feedback shift register (LFSR) 50 drive respective inputs of DAC 14E. DAC 14E is driven in part by the output signal of TDC 34, and is used as part of the proportional path control of DPLL 10.

In some embodiments, such as the embodiment in FIG. 3, DAC 14 (which in the example shown includes DACs 14A-14E) is implemented as a non-radix 2 DAC. For example, a radix of about 1.6 DAC may be used to create overlap in the digital to frequency mapping of ICO 16. The overlap avoids the situation where DPLL 10 locks on a DAC boundary that might cause excess or relatively large jitter or spurs in the output signal of DPLL 10.

In the exemplary embodiment shown, LFSR 50 has a characteristic polynomial x⁹+x⁵+1. As persons of ordinary skill in the art will understand, however, depending on the details of a particular application, other characteristic polynomials may be used, as desired.

Note that the use of LFSR 50 may be optional in some applications. Specifically, in some applications, the use of LFSR 50 might help avoid limit cycles once DPLL 10 has locked and thus operates as a Type 1 PLL. In situations where limit cycles exist, LFSR 50 may be used to break up the limit cycles. Otherwise, LFSR 50 may be omitted.

The outputs of DACs 14A-14E are coupled to scaling circuits 42A-42D in order to weight and scale the signals corresponding to the integral and proportional control paths of DPLL 10. More specifically, the current output signals of DAC 14C and DAC 14D are added together in summer 48. The output of summer 48 is scaled by 1/14 using scaling circuit 42C.

Similarly, the output signal of DAC 14A is scaled by 14 using scaling circuit 42A. The output signal of DAC 14B is scaled by 1 (unity) using scaling circuit 42B. Finally, the output signal of DAC 14E is scaled by a relatively small scaling factor (denoted as “V”) using scaling circuit 42D. In exemplary embodiments, the scaling factor V may be less than ¼.

The outputs of scaling circuits 42A-42D drive respective inputs of summer 44. Thus, summer 44 sums the currents corresponding to the output signals of scaling circuits 42A-42D to generate a sum current. The sum current at the output of summer 44 is used to provide the supply to the current-starved ring oscillator 46.

In the embodiment shown, ring oscillator 46 is implemented using three cascade-coupled inverters. As persons of ordinary skill in the art will understand, however, other arrangements, such as different numbers of inverters, may be used, as desired. The output signal of one of the inverts in ring oscillator 46 constitutes the output signal of ICO 16.

As noted above, DPLLs according to various embodiments have a number of advantageous characteristics. DPLLs according to various embodiments do not use any software-based calibration routines to cover a relatively large ICO output frequency range of 1.3 to 2.7 GHz. DPLLs according to various embodiments operate and properly lock over a relatively large output frequency range and over relatively large process, voltage, and temperature (PVT) ranges or variations without using a dedicated calibration operation or routine.

For instance, consider the frequency range shown in FIG. 2 and discussed above, i.e., 1300 to 2700 MHz. Typically a ring oscillator, such as ring oscillator 46 (or ICO 16 in FIG. 2), has relatively large variations in the frequency of its output signal over PVT variations as a result of which locking the output frequency of the DPLL over the 1300-2700 MHz range conventionally uses a calibration phase or operation, often with firmware intervention.

DPLLs according to various embodiments, however, can lock over relatively broad frequency ranges, such as 1300-2700 MHz, without using a calibration routine or operation. More specifically, no state machine or controller is used to perform power-up calibration. Rather, at power-up, the three detectors described above (fine frequency detector 36, coarse frequency detector 38, and TDC 34) operate simultaneously in order to achieve frequency and phase lock.

Thus, DPLLs according to various embodiments have automatic frequency detection and adaptation in addition to phase detection in order to achieve frequency and phase lock. Furthermore, the frequency detection is performed such as that relatively rapid frequency and phase lock is achieved, for example, 30 μs in exemplary embodiments.

DPLLs according to various embodiments provide relatively good performance characteristics. For example, DPLL 10 in FIG. 2 achieves a phase noise of −89.1 dBc at a 1-MHz offset when delivering an output signal with a frequency of 2.4 GHz. The design operates from 1.62 to 2.0V, consumes 1.4 mA when delivering an output signal with a frequency of 2.4 GHz.

As noted above, DPLLs according to various embodiments may be used in RF receivers, RF transmitters, and RF transceivers. As mere examples and without limitation, in RF transmitters or the transmitter portion of RF transceivers, one or more signals generated by DPLLs may be used to perform various functions. For example, in various embodiments, such signals may be used for clocking digital and/or mixed-signal circuitry (e.g., ADCs), mixing baseband signals to generate IF signals, and/or mixing IF signals to generate RF signals, etc.

As mere examples and without limitation, in RF receivers or the receiver portion of RF transceivers, one or more signals generated by DPLLs may be used to perform various functions. For example, in various embodiments, such signals may be used for clocking digital and/or mixed-signal circuitry (e.g., digital-to-analog converters (DACs)), mix RF signals to generate IF signals, mix IF signals to generate baseband signals, and/or perform image-reject calibration (e.g., use the output signal of DPLL 10 as a test tone in a least means square (LMS) image-reject calibration procedure), etc.

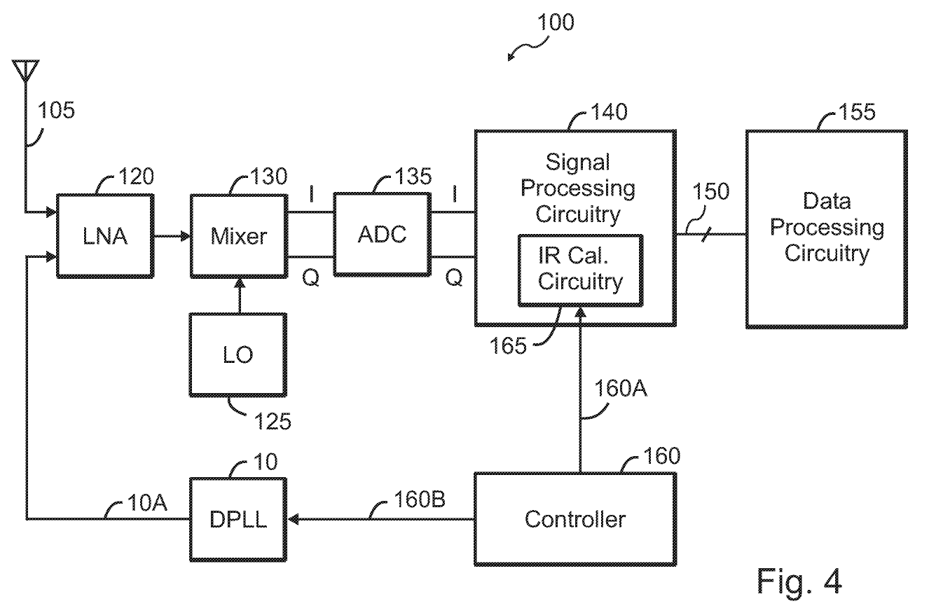

FIG. 4 shows a circuit arrangement for an RF receiver 100, including DPLL 10, according to an exemplary embodiment. Receiver 100 receives RF signals via antenna 105. The RF signals feed an input of low noise amplifier (LNA) 120. LNA 120 provides low-noise amplification of the RF signals, and provides amplified RF signals to mixer 130.

Mixer 130 performs frequency translation or shifting of the RF signals, using a reference or local oscillator (LO) frequency provided by LO 125. For example, in some embodiments, mixer 30 translates the RF signal frequencies to baseband frequencies. As another example, in some embodiments, mixer 30 translates the RF signal frequencies to an intermediate frequency (IF).

Mixer 130 provides the translated output signal as a set of two signals, an in-phase (I) signal, and a quadrature (Q) signal. The I and Q signals are analog time-domain signals. Analog-to-digital converter (ADC) 135 converts the I and Q signals to digital I and Q signals. In exemplary embodiments, ADC 135 may use a variety of signal conversion techniques. For example, in some embodiments, ADC 135 may use delta-sigma (or sometimes called sigma-delta) analog-to-digital conversion.

ADC 135 provides the digital I and Q signals to signal processing circuitry 140. Generally speaking, signal processing circuitry 140 performs processing on the digital I and Q signals, for example, digital signal processing (DSP). Signal processing circuitry 140 provides information, such as the demodulated data, to data processing circuitry 155 via link 150. Data processing circuitry 155 may perform a variety of functions (e.g., logic, arithmetic, etc.). For example, data processing circuitry 155 may use the demodulated data in a program, routine, or algorithm (whether in software, firmware, hardware, or a combination) to perform desired control or data processing tasks.

In some embodiments, data processing circuitry 155 may perform control of other circuitry, sub-system, or systems (not shown). In some embodiments, data processing circuitry 155 may provide the data (after processing, as desired, for example, filtering) to another circuit (not shown), such as a transducer, display, etc.

In exemplary embodiments, link 150 may take a variety of forms. For example, in some embodiments, link 150 may constitute a number of conductors or coupling mechanisms, such as wires, cables, printed circuit board (PCB) traces, etc. Through link 150, signal processing circuitry 140 and data processing circuitry 155 may exchange information, such as the demodulated data, control information or signals, status signals, etc., as desired.

Receiver 100 includes image reject (IR) calibration circuitry 165 that may be used to perform image reject calibration, as mentioned above. Receiver 100 further includes controller 160. Controller 160 uses an output signal 160A to control the operation of IR calibration circuitry 165. Controller 160 further uses output signal 160B to control the operation of DPLL 10, e.g., cause DPLL 10 to provide an output signal 10A as a test tone to the receiver. The test tone is typically injected into the receive path circuitry at a strategic location. In the exemplary embodiment shown in FIG. 4, the test tone output by DPLL 10 is applied at the input of LNA 120. IR calibration circuitry 165 residing after ADC 135 utilizes the LMS technique (or an alternate the technique) to calibrate the image rejection of the receive path circuitry.

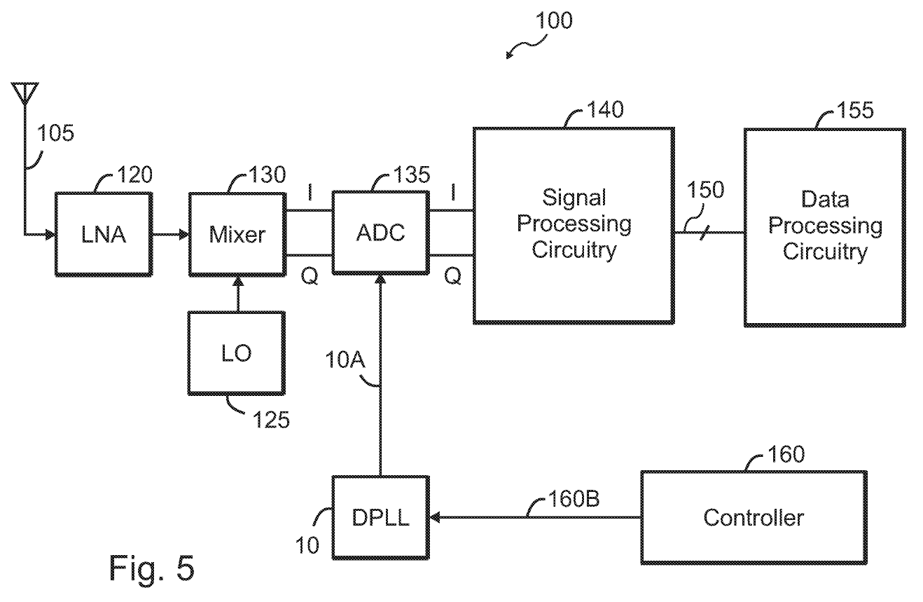

As noted above, DPLLs according to various embodiments may be used to clock ADC 135. FIG. 5 shows such an arrangement. In this scenario, DPLL 10 provides output signal 10A to ADC 135 in response to control signal 160B from controller 160. ADC 135 uses output signal 10A of DPLL 10 as a clock signal in order to perform analog-to-digital conversion.

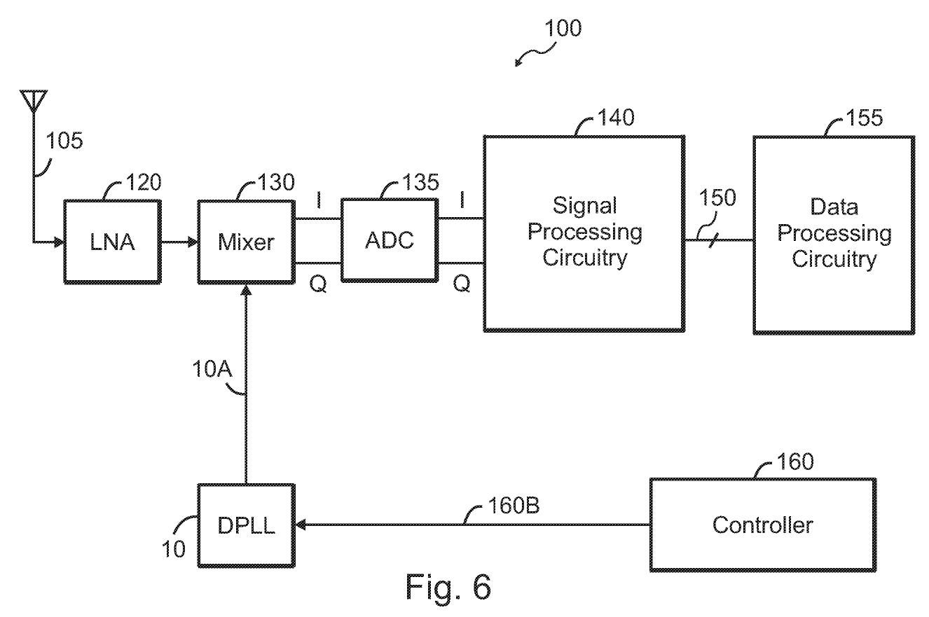

As further noted above, DPLLs according to various embodiments may be used to perform mixing operations. FIG. 6 shows such an arrangement. In this embodiment, LO 125 (see FIGS. 4-5) is omitted. Instead, output signal 10A of DPLL 10 is used as an LO signal. DPLL 10 provides output signal 10A to ADC 135 in response to control signal 160B from controller 160. Output signal 10A is used by mixer 130 to mix an RF signal with output signal 10A in order to generate the I and Q signals that are provided to ADC 135.

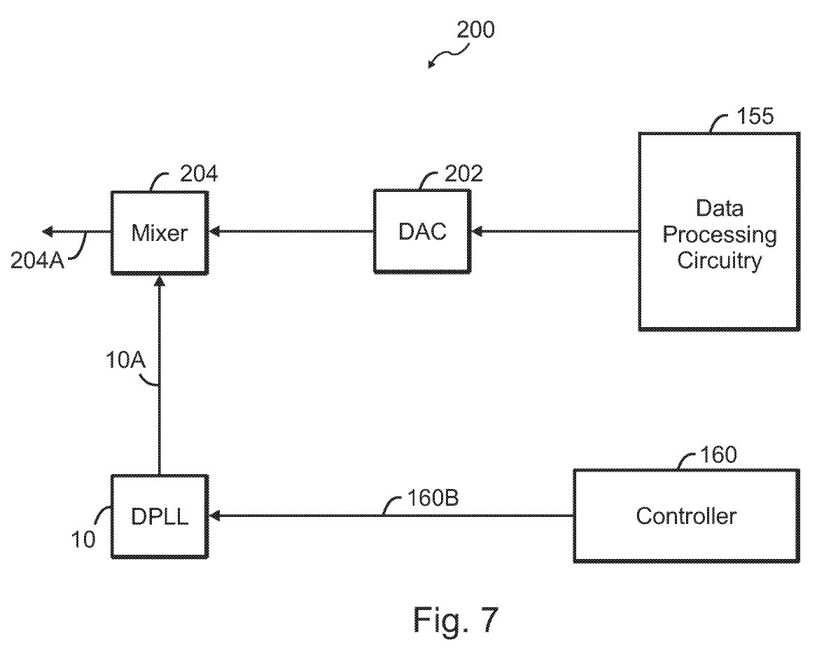

As noted above, DPLLs according to various embodiments may be used in RF transmitters. FIG. 7 shows a circuit arrangement for an RF transmitter (TX) 200, including DPLL 10, according to an exemplary embodiment. Data processing circuitry 155 provides a digital signal to DAC 202. DAC 202 converts the digital signal to an analog signal and provides the analog signal to mixer 204.

In response to control signal 160B from controller 160, DPLL 10 generates output signal 10A with a desired frequency (typically in the RF range). Mixer 204 mixes the output signal of DAC 202 with output signal 10A of DPLL 10. The resulting output signal 204A of mixer 204 may be provided to a power amplifier (not shown) or be further processed as part of the operations of transmitter 200.

Note that RF receiver 100 and RF transmitter 200 shown in the figures and described above constitute mere examples. As persons of ordinary skill in the art will understand, DPLLs according to various embodiments may be used in a variety of RF receivers (e.g., direct conversion, low-IF, etc.) and RF transmitters (direct-conversion, offset-PLL, etc.), as desired.

Note further that DPLLs according to various embodiments may also be used in RF transceivers. For example, by combining the functionality and/or circuitry of RF receivers that include one or more DPLLs with the functionality and/or circuitry of RF transmitters that include one or more DPLLs, RF transceivers may be realized, as persons of ordinary skill in the art will understand. In some embodiments, one or more DPLLs may be shared between the RF receiver and the RF transmitter, as persons of ordinary skill in the art will understand.

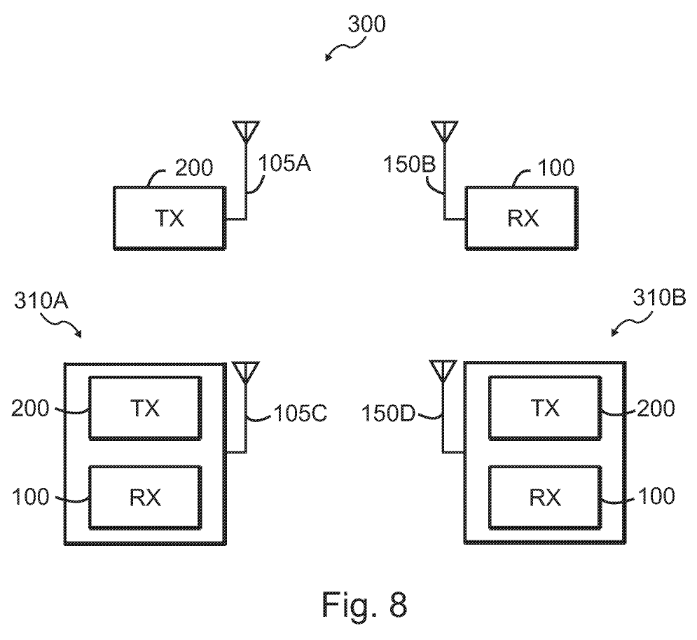

Furthermore, RF receivers, RF transmitters, and/or RF transceivers including DPLLs according to various embodiments may be used in a variety of communication arrangements, systems, sub-systems, networks, etc., as desired. FIG. 8 shows a circuit arrangement for an RF communication system according to an exemplary embodiment.

System 300 includes a transmitter 200, coupled to antenna 105A. Via antenna 105A, transmitter 200 transmits RF signals. The RF signals may be received by receiver 100, described above. In addition, or alternatively, transceiver 310A and/or transceiver 310B might receive (via receiver 100) the transmitted RF signals.

In addition to receive capability, transceiver 310A and transceiver 310B can also transmit RF signals. The transmitted RF signals might be received by receiver 100, either in the stand-alone receiver, or via the receiver circuitry of the non-transmitting transceiver.

Other systems or sub-systems with varying configuration and/or capabilities are also contemplated. For example, in some exemplary embodiments, two or more transceivers (e.g., transceiver 310A and transceiver 310B) might form a network, such as an ad-hoc network, a mesh network, etc. As another example, in some exemplary embodiments, transceiver 310A and transceiver 310B might form part of a network, for example, in conjunction with transmitter 200.

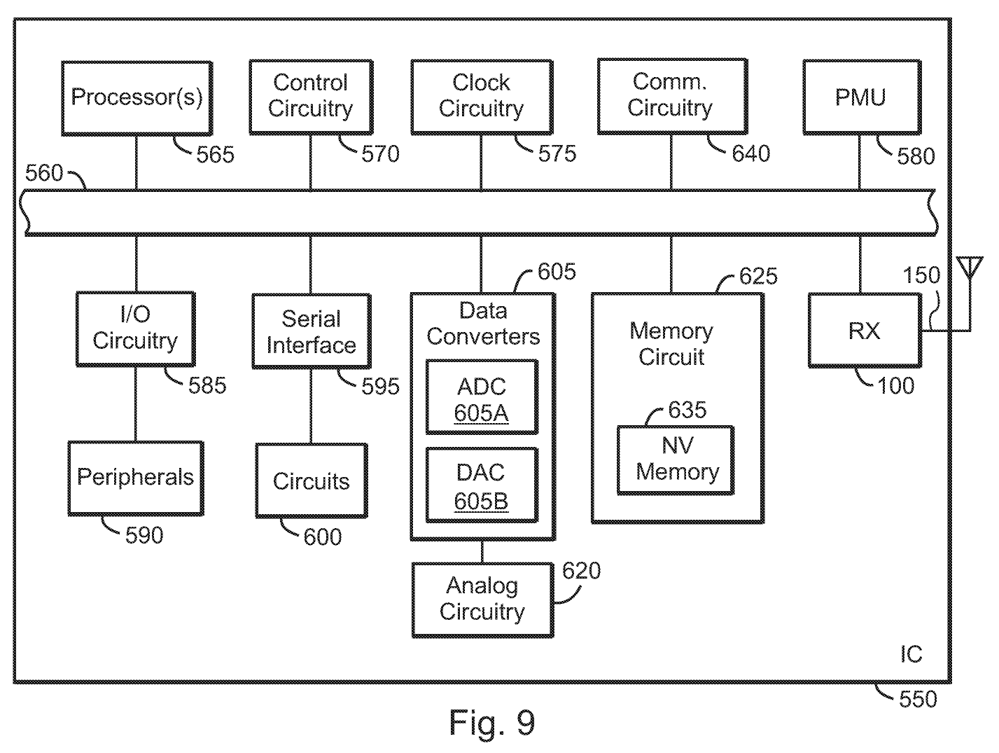

RF receivers and RF transmitters, such as RF receiver 100 and RF transmitter 200 described above, may be used in a variety of circuits, blocks, subsystems, and/or systems. For example, in some embodiments, such RF receivers may be integrated in an IC, such as an MCU. FIG. 9 shows a circuit arrangement for an IC, including RF receiver 100 that includes one or more DPLLs (e.g., as shown in FIGS. 4-6), according to an exemplary embodiment.

The circuit arrangement includes an IC 550, which constitutes or includes an MCU. IC 550 includes a number of blocks (e.g., processor(s) 565, data converter 605, I/O circuitry 585, etc.) that communicate with one another using a link 560. In exemplary embodiments, link 560 may constitute a coupling mechanism, such as a bus, a set of conductors or semiconductor elements (e.g., traces, devices, etc.) for communicating information, such as data, commands, status information, and the like.

IC 550 may include link 560 coupled to one or more processors 565, clock circuitry 575, and power management circuitry or power management unit (PMU) 580. In some embodiments, processor(s) 565 may include circuitry or blocks for providing information processing (or data processing or computing) functions, such as central-processing units (CPUs), arithmetic-logic units (ALUs), and the like. In some embodiments, in addition, or as an alternative, processor(s) 565 may include one or more DSPs. The DSPs may provide a variety of signal processing functions, such as arithmetic functions, filtering, delay blocks, and the like, as desired. In some embodiments, functionality of parts of receiver 100, such as those described above, may be implemented or realized using some of the circuitry in processor(s) 565, as desired

Referring again to FIG. 9, clock circuitry 575 may generate one or more clock signals that facilitate or control the timing of operations of one or more blocks in IC 550. Clock circuitry 575 may also control the timing of operations that use link 560, as desired. In some embodiments, clock circuitry 575 may provide one or more clock signals via link 560 to other blocks in IC 550.

In some embodiments, PMU 580 may reduce an apparatus's (e.g., IC 550) clock speed, turn off the clock, reduce power, turn off power, disable (or power down or place in a lower power consumption or sleep or inactive or idle state), enable (or power up or place in a higher power consumption or normal or active state) or any combination of the foregoing with respect to part of a circuit or all components of a circuit, such as one or more blocks in IC 550. Further, PMU 580 may turn on a clock, increase a clock rate, turn on power, increase power, or any combination of the foregoing in response to a transition from an inactive state to an active state (including, without limitation, when processor(s) 565 make a transition from a low-power or idle or sleep state to a normal operating state).

Link 560 may couple to one or more circuits 600 through serial interface 595. Through serial interface 595, one or more circuits or blocks coupled to link 560 may communicate with circuits 600. Circuits 600 may communicate using one or more serial protocols, e.g., SMBUS, I²C, SPI, and the like, as person of ordinary skill in the art will understand.

Link 560 may couple to one or more peripherals 590 through I/O circuitry 585. Through I/O circuitry 585, one or more peripherals 590 may couple to link 560 and may therefore communicate with one or more blocks coupled to link 560, e.g., processor(s) 565, memory circuit 625, etc.

In exemplary embodiments, peripherals 590 may include a variety of circuitry, blocks, and the like. Examples include I/O devices (keypads, keyboards, speakers, display devices, storage devices, timers, sensors, etc.). Note that in some embodiments, some peripherals 590 may be external to IC 550. Examples include keypads, speakers, and the like.

In some embodiments, with respect to some peripherals, I/O circuitry 585 may be bypassed. In such embodiments, some peripherals 590 may couple to and communicate with link 560 without using I/O circuitry 585. In some embodiments, such peripherals may be external to IC 550, as described above.

Link 560 may couple to analog circuitry 620 via data converter(s) 605. Data converter(s) 605 may include one or more ADCs 605A and/or one or more DACs 605B.

ADC(s) 605A receive analog signal(s) from analog circuitry 620, and convert the analog signal(s) to a digital format, which they communicate to one or more blocks coupled to link 560. Conversely, DAC(s) 605B receive digital signal(s) from one or more blocks coupled to link 560, and convert the digital signal(s) to analog format, which they communicate to analog circuitry 620.

Analog circuitry 620 may include a wide variety of circuitry that provides and/or receives analog signals. Examples include sensors, transducers, and the like, as person of ordinary skill in the art will understand. In some embodiments, analog circuitry 620 may communicate with circuitry external to IC 550 to form more complex systems, sub-systems, control blocks or systems, feedback systems, and information processing blocks, as desired.

Control circuitry 570 couples to link 560. Thus, control circuitry 570 may communicate with and/or control the operation of various blocks coupled to link 560 by providing control information or signals. In some embodiments, control circuitry 570 also receives status information or signals from various blocks coupled to link 560. In addition, in some embodiments, control circuitry 570 facilitates (or controls or supervises) communication or cooperation between various blocks coupled to link 560.

In some embodiments, control circuitry 570 may initiate or respond to a reset operation or signal. The reset operation may cause a reset of one or more blocks coupled to link 560, of IC 550, etc., as person of ordinary skill in the art will understand. For example, control circuitry 570 may cause PMU 580, and circuitry such as RF receiver 10, to reset to an initial or known state.

In exemplary embodiments, control circuitry 570 may include a variety of types and blocks of circuitry. In some embodiments, control circuitry 570 may include logic circuitry, finite-state machines (FSMs), or other circuitry to perform operations such as the operations described above.

Communication circuitry 640 couples to link 560 and also to circuitry or blocks (not shown) external to IC 550. Through communication circuitry 640, various blocks coupled to link 560 (or IC 550, generally) can communicate with the external circuitry or blocks (not shown) via one or more communication protocols. Examples of communications include USB, Ethernet, and the like. In exemplary embodiments, other communication protocols may be used, depending on factors such as design or performance specifications for a given application, as person of ordinary skill in the art will understand.

As noted, memory circuit 625 couples to link 560. Consequently, memory circuit 625 may communicate with one or more blocks coupled to link 560, such as processor(s) 365, control circuitry 570, I/O circuitry 585, etc.

Memory circuit 625 provides storage for various information or data in IC 550, such as operands, flags, data, instructions, and the like, as persons of ordinary skill in the art will understand. Memory circuit 625 may support various protocols, such as double data rate (DDR), DDR2, DDR3, DDR4, and the like, as desired.

In some embodiments, memory read and/or write operations by memory circuit 625 involve the use of one or more blocks in IC 550, such as processor(s) 565. A direct memory access (DMA) arrangement (not shown) allows increased performance of memory operations in some situations. More specifically, DMA (not shown) provides a mechanism for performing memory read and write operations directly between the source or destination of the data and memory circuit 625, rather than through blocks such as processor(s) 565.

Memory circuit 625 may include a variety of memory circuits or blocks. In the embodiment shown, memory circuit 625 includes non-volatile (NV) memory 635. In addition, or instead, memory circuit 625 may include volatile memory (not shown), such as random access memory (RAM). NV memory 635 may be used for storing information related to performance, control, or configuration of one or more blocks in IC 550. For example, NV memory 635 may store configuration information related to RF receiver 100 and/or to initial or ongoing configuration or control of RF receiver 100 (including DPLL(s) included in RF receiver 100), as desired.

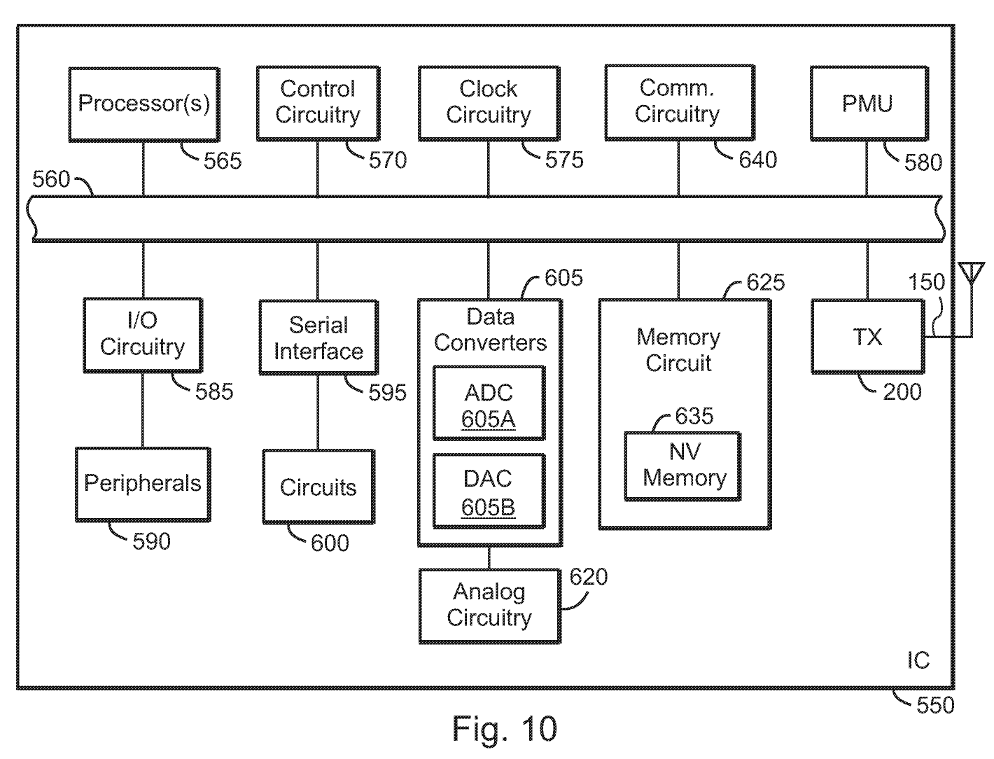

As noted, DPLLs according to various embodiments may also be used in RF transmitters. Such RF transmitters may be included in various electronic circuitry, such as ICs. FIG. 10 shows a circuit arrangement for an IC 500, including an RF transmitter 200 that includes one or more DPLLs, according to an exemplary embodiment. RF transmitter 200 may be coupled to and operate in conjunction with various blocks and circuitry in IC 550, as described above.

Various circuits and blocks described above and used in exemplary embodiments may be implemented in a variety of ways and using a variety of circuit elements or blocks. For example, phase and frequency detector 12, DAC 14, ICO 16, MMD 18, frequency divider 22, current-controlled oscillator (ICO) 16, multi-modulus divider (MMD) 18, TDC 34, fine frequency detector 36, coarse frequency detector 38, up-down counters 24, frequency divider 26, selector 28, binary to thermometer encoders 40A-40D, summer 48, scaling circuits 42A-42D, summer 44, ring oscillator 46, LFSR 50, LNA 120, mixer 130, LO 125, ADC 135, signal processing circuitry 140, data processing circuitry 155, IR calibration circuitry 165, DAC 202, mixer 204 may generally be implemented using gates, digital multiplexers (MUXs), latches, flip-flops, registers, finite state machines (FSMs), processors, programmable logic (e.g., field programmable gate arrays (FPGAs) or other types of programmable logic), arithmetic-logic units (ALUs), standard cells, custom cells, custom analog cells, etc., as desired, and as persons of ordinary skill in the art will understand. In addition, analog circuitry or mixed-signal circuitry or both may be included, for instance, power converters, discrete devices (transistors, capacitors, resistors, inductors, diodes, etc.), and the like, as desired. The analog circuitry in the blocks and circuits above may be implemented using bias circuits, decoupling circuits, coupling circuits, supply circuits, current mirrors, current and/or voltage sources, filters, amplifiers, converters, signal processing circuits (e.g., multipliers), detectors, transducers, discrete components (transistors, diodes, resistors, capacitors, inductors), analog MUXs and the like, as desired, and as persons of ordinary skill in the art will understand. The mixed-signal circuitry may include analog-to-digital converters (ADCs), digital-to-analog converters (DACs), etc.) in addition to analog circuitry and digital circuitry, as described above, and as persons of ordinary skill in the art will understand. The choice of circuitry for a given implementation depends on a variety of factors, as persons of ordinary skill in the art will understand. Such factors include design specifications, performance specifications, cost, IC or device area, available technology, such as semiconductor fabrication technology), target markets, target end-users, etc.

Referring to the figures, persons of ordinary skill in the art will note that the various blocks shown might depict mainly the conceptual functions and signal flow. The actual circuit implementation might or might not contain separately identifiable hardware for the various functional blocks and might or might not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation. Other modifications and alternative embodiments in addition to the embodiments in the disclosure will be apparent to persons of ordinary skill in the art. Accordingly, the disclosure teaches those skilled in the art the manner of carrying out the disclosed concepts according to exemplary embodiments, and is to be construed as illustrative only. Where applicable, the figures might or might not be drawn to scale, as persons of ordinary skill in the art will understand.

The particular forms and embodiments shown and described constitute merely exemplary embodiments. Persons skilled in the art may make various changes in the shape, size and arrangement of parts without departing from the scope of the disclosure. For example, persons skilled in the art may substitute equivalent elements for the elements illustrated and described. Moreover, persons skilled in the art may use certain features of the disclosed concepts independently of the use of other features, without departing from the scope of the disclosure.

1. An apparatus, comprising:
a digital phase-locked loop (DPLL) comprising:
a digital phase and frequency detector coupled to receive a reference signal and to generate a first set of output signals;
a digital loop filter that receives the first set of output signals of the phase and frequency detector output and generates an integral path control signal and a proportional path control signal;
a digital to analog converter (DAC) to convert the integral path control signal and the proportional path control signal to a second set of output signals; and
a controlled oscillator (CO) to generate an output signal in response to the second set of output signals.

2. The apparatus according to claim 1, wherein the digital loop filter comprises a plurality of up-down counters coupled to the digital phase and frequency detector to provide the integral path control signal.

3. The apparatus according to claim 1, wherein either: (a) the DAC comprises a current DAC and the CO comprises a current-controlled oscillator (ICO), or (b) the DAC comprises a voltage DAC and the CO comprises a voltage-controlled oscillator (VCO).

4. The apparatus according to claim 1, wherein the digital phase and frequency detector comprises:
a time to digital converter (TDC);
a fine frequency detector; and
a coarse frequency detector.

5. The apparatus according to claim 4, wherein the fine frequency detector comprises a rotational frequency detector or quadri-correlator circuit, and wherein the coarse frequency detector comprises a set of digital counters.

6. The apparatus according to claim 1, wherein the DPLL prioritizes and weights an output of the coarse frequency detector highest, followed by an output of the fine frequency detector, and an output of the TDC lowest.

7. The apparatus according to claim 1, wherein the DAC comprises a non-radix 2 DAC.

8. An apparatus, comprising:
a digital phase-locked loop (DPLL) comprising:
a plurality of up-down counters;
a time-to-digital converter (TDC) coupled to the plurality of up-down counters;
a fine frequency detector coupled to the plurality of up-down counters; and
a coarse frequency detector coupled to the plurality of up-down counters.

9. The apparatus according to claim 8, wherein the DPLL further comprises a plurality of binary-to-thermometer encoders coupled to the plurality of up-down counters.

10. The apparatus according to claim 9, wherein the DPLL further comprises a digital-to-analog converter (DAC) coupled to the plurality of binary-to-thermometer encoders.

11. The apparatus according to claim 10, wherein either: (a) the DAC comprises a current DAC and the DPLL further comprises a current-controlled oscillator (ICO) coupled to the current DAC, or (b) the DAC comprises a voltage DAC and DPLL further comprises a voltage-controlled oscillator (VCO) coupled to the voltage DAC.

12. An apparatus, comprising:
a digital phase-locked loop (DPLL) comprising:
a digital phase and frequency detector, the digital phase and frequency detector comprising a time to digital converter (TDC), a fine frequency detector, and a coarse frequency detector,
wherein the DPLL achieves a frequency lock of an output signal of the DPLL without using a calibration operation.

13. The apparatus according to claim 12, wherein upon power-up of the DPLL the TDC, the fine frequency detector, and the coarse frequency detector operate simultaneously in order to achieve the frequency lock of the output signal of the DPLL.

14. The apparatus according to claim 12, wherein the DPLL further comprises a plurality of up-down counters coupled to the digital phase and frequency detector.

15. The apparatus according to claim 14, wherein the DPLL further comprises a plurality of binary-to-thermometer encoders coupled to the plurality of up-down counters.

16. The apparatus according to claim 15, wherein the DPLL further comprises a plurality of digital-to-analog converter (DAC) circuits coupled to the plurality of binary to thermometer encoders.

17. The apparatus according to claim 16, wherein the plurality of DAC circuits comprise non-radix 2 DAC circuits.

18. The apparatus according to claim 12, wherein the DPLL further comprises a controlled oscillator (CO) that generates an output signal in response to control signals derived from output signals of the digital phase and frequency detector.

19. The apparatus according to claim 18, wherein the ICO comprises:
a plurality of scaling circuits;
a summer to sum output signals of the plurality of scaling circuits; and
a ring oscillator having a supply voltage that is derived from an output signal of the summer.

20. The apparatus according to claim 12, wherein the DPLL operates as a Type 2 phase-locked loop (PLL) while a frequency of the output signal of the DPLL is being corrected, and wherein the DPLL operates as a Type 1 PLL when the frequency and phase of the output signal of the DPLL has been acquired.
